(19) United States
(12) Patent Application Publication
(10) Pub. No.: US 2009/0166431 A1
(43) Pub. Date: Jul. 2, 2009

(54) ELECTRONIC COMPONENT AND MANUFACTURING METHOD THEREOF

(75) Inventor: Hiroshi Aoyama, Hyogo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: HALLYS CORPORATION, Akashi-shi (JP)

(21) Appl. No.: 11/911,344

(22) PCT Filed: Apr. 17, 2006
(86) PCT No.: PCT/JP2006/308082

§ 371 Date: Oct. 12, 2007

(30) Foreign Application Priority Data
Apr. 18, 2005 (JP) 2005-119433

(51) Int. Cl. H05K 1/18; H01L 21/52; G06K 19/06

(52) U.S. Cl. 235/492; 438/118; 361/783; 257/E21.5

(57) ABSTRACT

The invention relates to an RFID medium 1 in which an interposer 10 having a semiconductor chip 11 mounted on a sheet-like chip holding member 13 is bonded to a sheet-like base circuit sheet 20. The interposer 10 has the IC chip 11 mounted on a substantially planar surface of the chip holding member 13, and an interposer terminal that is electrically extended from a terminal of the IC chip 11. The base circuit sheet 20 has a base terminal 22 electrically connected to the interposer terminal 12, and has a through chip housing portion 210 for housing the semiconductor chip 11 on the interposer 10.

### CROSS-REFERENCES TO RELATED APPLICATIONS

This is a US National Stage of International patent application PCT/JP2006/308082 filed Apr. 17, 2006, and claims the benefit of priority of Japanese patent application 2005-119433 filed Apr. 18, 2005.

### TECHNICAL FIELD

The present invention relates to an electronic component configured using an interposer having a semiconductor chip mounted thereon.

### BACKGROUND ART

There has been known a noncontact IC tag, that is, an RFID tag in which, for example, an interposer having a semiconductor chip mounted on a surface of a resin film is bonded to a film sheet having an antenna pattern. Some of the interposers have an interposer terminal as an enlarged electrode electrically extended from a terminal of the semiconductor chip. Such an interposer having the interposer terminal is used to allow the RFID tag to be easily and electrically reliably produced as compared with the case where the semiconductor chip is directly mounted on the antenna sheet (for example, refer to Patent Document 1).

However, an electronic component, for example, the RFID tag using the conventional interposer has the following problems. Specifically, the interposer has the semiconductor chip mounted on the surface facing the antenna sheet, and thus has an irregular bonding surface on the side of the antenna sheet. The interposer having the irregular bonding surface cannot be easily bonded to the antenna sheet with high reliability.

Patent Document 1: Japanese Patent Laid-Open No. 2003-6601

### DISCLOSURE OF THE INVENTION

The present invention has an object to provide an electronic component configured using an interposer and in which the interposer is bonded with high reliability, and a production method of the electronic component.

The first invention provides an electronic component in which an interposer having a semiconductor chip mounted on a sheet-like chip holding member is bonded to a sheet-like base circuit sheet, characterized in that the interposer has the semiconductor chip mounted on a substantially planar surface of the chip holding member and has an interposer terminal that is a conductive pattern electrically extended from a terminal of the semiconductor chip, and the base circuit sheet has a base terminal electrically connected to the interposer terminal and includes a chip housing portion for housing the semiconductor chip.

The base circuit sheet that constitutes the electronic component of the first invention includes the chip housing portion for housing the semiconductor chip on the interposer. The base circuit sheet including the chip housing portion can accommodate irregularities on the surface of the interposer in stacking the interposer. Thus, the base circuit sheet can be brought into tight contact with the interposer with high reliability. The base circuit sheet and the interposer that are brought into tight contact with each other can be bonded with high reliability.

Also, the interposer and the base circuit sheet are bonded with the semiconductor chip being housed in the chip housing portion to prevent the risk of applying an excessive bonding load to the semiconductor chip. This can prevent the risk of causing initial trouble of the semiconductor chip in a production process. Thus, the electronic component has high production efficiency and high quality.

Further, the combination of the chip housing portion in the base circuit sheet and the semiconductor chip on the interposer allows positioning in stacking the base circuit sheet and the interposer with high reliability, and can increase stacking accuracy. The electronic component of the first invention with increased stacking accuracy has high electrical reliability and high production efficiency.

As described above, in the electronic component of the first invention, the interposer and the base circuit sheet are bonded with high reliability, and initial trouble of the semiconductor chip is prevented. Thus, the electronic component has high initial quality and can maintain the high initial quality over a long period of time.

The second invention provides a production method for producing an electronic component in which an interposer having a semiconductor chip mounted on a surface of a sheet-like chip holding member and having an interposer terminal that is a conductive pattern electrically extended from a terminal of the semiconductor chip is bonded to a sheet-like base circuit sheet having a base terminal electrically connected to the interposer terminal, including: a chip mounting step of mounting the semiconductor chip on the surface of the chip holding member, a housing portion forming step of providing a chip housing portion for housing the semiconductor chip in the base circuit sheet, a stacking step of stacking the base circuit sheet and the interposer so that the semiconductor chip is housed in the chip housing portion, and a bonding step of bonding the base circuit sheet and the interposer that are stacked.

The production method for producing an electronic component of the second invention includes the housing portion forming step of forming the chip housing portion in the base circuit sheet. In the stacking step, the interposer having the semiconductor chip mounted on the surface is stacked on the base circuit sheet having the chip housing portion with high sealability. Thus, in the bonding step, the base circuit sheet and the interposer that are stacked with high sealability can be bonded with high reliability. Also, the electronic component produced by the production method for producing an electronic component of the second invention has high reliability and high quality.

### BRIEF DESCRIPTION OF THE DRAWINGS

FIG. 1 is a sectional view of a sectional structure of an RFID medium in Embodiment 1;

FIG. 2 is a front view of an interposer in Embodiment 1;

FIG. 3 is a sectional view of a sectional structure of the interposer in Embodiment 1;

FIG. 4 is a perspective view of an antenna sheet in Embodiment 1;

FIG. 5 illustrates a housing portion forming step in Embodiment 1;

FIG. 6 illustrates a stacking step in Embodiment 1;

FIG. 7 is an enlarged sectional view of a bonding section of the RFID medium in Embodiment 1;

FIG. 8 illustrates a housing portion forming step in Embodiment 2;

FIG. 9 is a perspective view of an antenna sheet in Embodiment 2;

FIG. 10 illustrates a state of stacking an interposer and the antenna sheet in a stacking step in Embodiment 2;

FIG. 11 is a sectional view of a stacking structure of the interposer and the antenna sheet in Embodiment 2;

FIG. 12 illustrates a bonding step in Embodiment 2;

FIG. 13 is a sectional view of a sectional structure of an RFID medium obtained by the bonding step in Embodiment 2;

FIG. 14 is a sectional view of a sectional structure of the RFID medium obtained by the bonding step in Embodiment 2;

FIG. 15 is a perspective view of an interposer and an antenna sheet in Embodiment 3; and

FIG. 16 is a perspective view of another antenna sheet in Embodiment 3.

### DESCRIPTION OF SYMBOLS

1 RFID medium
10 interposer
11 IC chip
12 interposer terminal
20 antenna sheet
210 chip housing portion
22 base terminal
24 antenna pattern

### BEST MODE FOR CARRYING OUT THE INVENTION

The chip housing portion in the first and the second inventions includes, for example, a recessed depression or a through hole. For example, a recessed chip housing portion can be formed by embossing or the like. Alternatively, for example, a through-hole-shaped chip housing portion passing through the base circuit sheet can be formed by press stamping or the like.

In the first invention, the chip holding member and the base circuit sheet are preferably made of resin films. In this case, the chip holding member and the base circuit sheet made of resin films can be used to form the electronic component with high flexibility.

It is preferable that the chip housing portion has a shape of a recessed depression, and the recessed chip housing portion houses the semiconductor chip via an insulating adhesive having electrical insulating properties. In this case, a fitting structure of the protruding semiconductor chip on the interposer and the recessed chip housing portion in the base circuit sheet can be positively used to significantly increase bonding strength between the interposer and the base circuit sheet.

It is preferable that the base circuit sheet has a through-hole-shaped chip housing portion, and has a pair of base terminals so as to face each other with the chip housing portion therebetween, and each of the base terminals is bonded to the interposer terminal via a conductive adhesive. In this case, the conductive adhesive that bonds between the base terminals and the interposer terminals is divided between the pair of base terminals by the through-hole-shaped chip housing portion. Thus, even when the base terminals and the interposer terminals are bonded using the conductive adhesive, electrical insulation between the pair of base terminals can be ensured with high reliability.

It is preferable that the chip holding member has a protruding or recessed engaging portion with the base circuit sheet, and the base circuit sheet has an engaged portion configured to fit the engaging portion. The engaged portion corresponding to the protruding engaging portion may be formed as a recessed depression like the chip housing portion, or may be formed as a through hole. The recessed or through-hole-shaped engaged portion may be formed integrally with the chip housing portion or formed independently. On the other hand, the recessed engaging portion may be formed as a closed-end recess or a through hole. The engaged portion corresponding to the recessed engaging portion has, for example, a protruding shape.

As described above, in the case where the engaged portion is provided in the base circuit sheet, and the engaging portion housed in the engaged portion is provided in the interposer, the combination of the engaged portion and the engaging portion allows positioning of the base circuit sheet and the interposer sheet with higher reliability. For example, when the interposer terminal has a polarity, the operation and effect of providing the engaging portion and the engaged portion is particularly effective.

It is preferable that the base circuit sheet has an antenna pattern for radio communication constituted by a conductive pattern, and the semiconductor chip is an RFID IC chip. In this case, the electronic component as an RFID tag has high electrical reliability and high quality with high durability.

In the second invention, it is preferable that the stacking step is a step of stacking the interposer on the base circuit sheet after applying an insulating adhesive having electrical insulating properties to at least a surface of the base terminal on the base circuit sheet, the bonding step is a step of pressing the base circuit sheet and the interposer using a pair of press dies facing each other, at least one of the base circuit sheet and the chip holding member is made of plastic material, and one of the press dies adjacent to the base circuit sheet or the chip holding member made of the plastic material has a protrusion protruding toward the other press die on a pressing surface facing a back surface of the interposer terminal or the base terminal.

In this case, the press die having the protrusion on the pressing surface is used to press the base circuit sheet or the chip holding member made of the plastic material. Particularly, the protrusion is positioned on the back surface of the interposer terminal or the base terminal. Thus, at least one of the interposer terminal and the base terminal can be protrudingly deformed toward the other. At the protrudingly deformed portion, the insulating adhesive can be positively drained, and the interposer terminal and the base terminal can be brought into direct contact. Thus, the interposer terminal and the base terminal can be brought into direct contact to ensure electrical connection with high reliability. On the other hand, at a non-protrudingly-deformed portion of the interposer terminal or the base terminal, the insulating adhesive between the terminals can ensure a physical connection with high reliability.

It is preferable that the insulating adhesive is thermoplastic, and the press die having the protrusion includes a heater for heating the pressing surface. In this case, the insulating adhesive can be heated to increase fluidity thereof. Thus, the insulating adhesive can be more easily drained from the protrudingly deformed portion by the protrusion. The direct contact between the interposer terminal and the base terminal can be achieved with higher reliability.

The insulating adhesive is preferably moisture-curable. In this case, the moisture-curable insulating adhesive can further increase bonding reliability between the interposer and the base circuit sheet.

Ultrasonic vibration is preferably applied between the interposer terminal and the base terminal in the bonding step. In this case, the ultrasonic vibration is applied between the interposer terminal and the base terminal to increase direct bonding strength therebetween. Further, electrical reliability of the electronic component can be further increased to increase durability thereof.

It is preferable that the base circuit sheet has an antenna pattern constituted by a conductive pattern, and the semiconductor chip is an RFID IC chip. In this case, reliability of the electronic component as the RFID tag can be increased, and production efficiency thereof can be increased.

### Embodiment 1

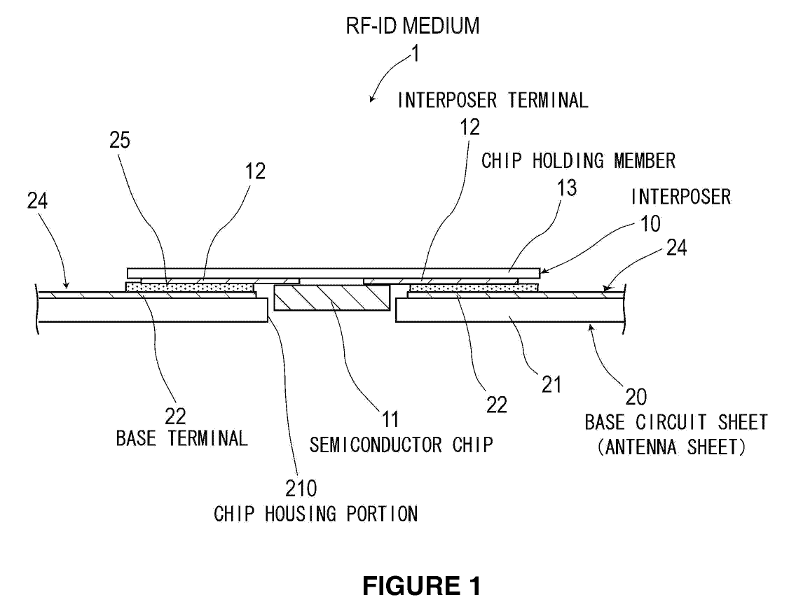

This embodiment relates to an RFID medium configured using an interposer. This will be described with reference to FIGS. 1 to 6. As shown in FIG. 1, this embodiment relates to an RFID medium that is an electronic component 1 (hereinafter referred to as an RFID medium 1) in which an interposer 10 having a semiconductor chip 11 mounted on a sheet-like chip holding member 13 is bonded to a sheet-like base circuit sheet 20. The interposer 10 has the semiconductor chip 11 mounted on a substantially planar surface of the chip holding member 13, and an interposer terminal 12 that is a conductive pattern electrically extended from a terminal of the semiconductor chip 11. An antenna sheet that is the base circuit sheet 20 (hereinafter referred to as an antenna sheet 20) has a base terminal 22 electrically connected to the interposer terminal 12, and a through chip housing portion 210 for housing the semiconductor chip 11. Now, this will be described in detail.

As described above, the electronic component of the embodiment is an RFID (Radio-Frequency Identification) medium for noncontact ID as shown in FIG. 1. The RFID medium 1 is constituted by stacking the interposer 10 having an RFID IC chip as the semiconductor chip 11 (hereinafter referred to as an IC chip 11 as appropriate) mounted thereon, and the antenna sheet 20 as the base circuit sheet.

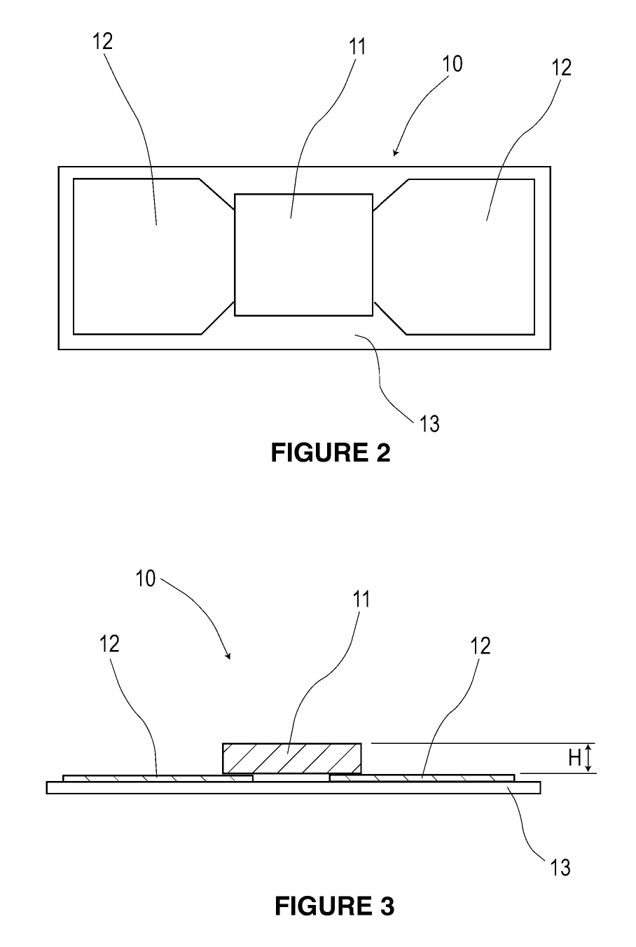

As shown in FIGS. 2 and 3, the interposer 10 has the IC chip 11 mounted on the surface of the sheet-like chip holding member 13 made of a PSF film. The chip holding member 13 has a thickness of 100 μm, and a rectangular shape of 3 mm long and 6 mm wide. The IC chip 11 has a mounting height H (FIG. 3) of 100 to 110 μm, and a size of 400 μm long and 400 μm wide. The chip holding member 13 may be made of PC, PET, processed paper, or the like instead of PSF in this embodiment.

On the surface of the chip holding member 13, the interposer terminal 12 electrically extended from a conductive pad (not shown) that abuts against the terminal of the IC chip 11 is provided. In the embodiment, the interposer terminal 12 is formed of conductive ink. The interposer terminal 12 may be formed by copper etching, dispensing, metal foil affixation, direct vapor deposition of metal, metal vapor deposition film transfer, formation of conductive polymer layer, or the like instead of a method of printing the conductive ink in the embodiment.

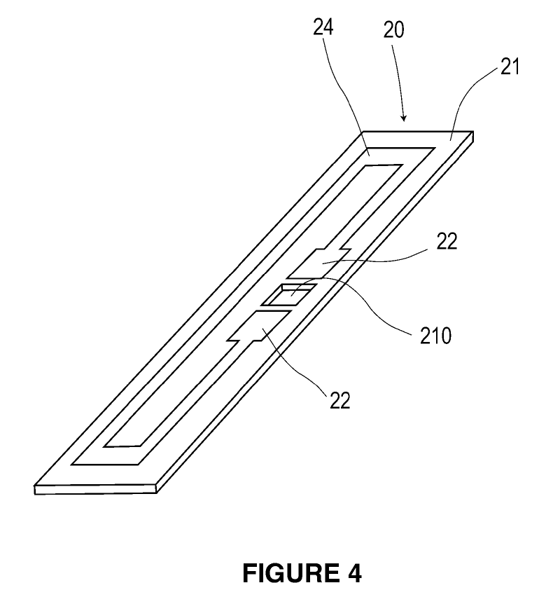

As shown in FIG. 4, the antenna sheet 20 is formed by printing an antenna pattern 24 formed of conductive ink on a surface of a sheet-like base member 21. The base member 21 in the embodiment is made of PET and is a sheet-like member having a thickness of 100 μm. The base member 21 may be made of PET-G, PC, PP, nylon, paper, or the like besides PET in the embodiment. The conductive ink that forms the antenna pattern 24 may be made of ink material such as silver, graphite, silver chloride, copper, or nickel. The antenna pattern 24 may be formed by copper etching, dispensing, metal foil affixation, direct vapor deposition of metal, metal vapor deposition film transfer, formation of conductive polymer layer, or the like instead of a method of printing the conductive ink in the embodiment.

As the antenna pattern 24, a substantially annular pattern with a break at one cut position is formed as shown in FIG. 4. Ends that form the cut position of the antenna pattern 24 constitute a pair of base terminals 22 for electrically connecting to the interposer terminals 12 (see FIG. 2). Particularly, the antenna sheet 20 in the embodiment has a through-hole-shaped chip housing portion 210 between the pair of base terminals 22 placed to face each other. The chip housing portion 210 is 800 μm long and 800 μm wide, and is configured to house the IC chip 11 (see FIG. 2). Instead of the through chip housing portion 210 in the embodiment, a recessed chip housing portion may be formed. Further, FIGS. 1 to 7 show the IC chip 11 deformed in size, and show a gap between an outer edge of the chip housing portion 210 and the IC chip 11 in a relatively smaller scale than an actual scale.

As shown in FIG. 1, the RFID medium 1 in the embodiment is formed by stacking the interposer 10 and the antenna sheet 20 so as to face each other. In the RFID medium 1, the surface mounted with the IC chip 11 of the interposer 10 and the surface formed with the antenna pattern 24 on the antenna sheet 20 face each other. The interposer 10 and the antenna sheet 20 are bonded by a conductive adhesive 25 between the interposer terminal 12 and the base terminal 22. Particularly, in the RFID medium 1 of the embodiment, the IC chip 11 protruding on the surface of the interposer 10 is housed in the chip housing portion 210 in the antenna sheet 20. This allows the interposer 10 and the antenna sheet 20 to be brought into tight contact with each other without a gap.

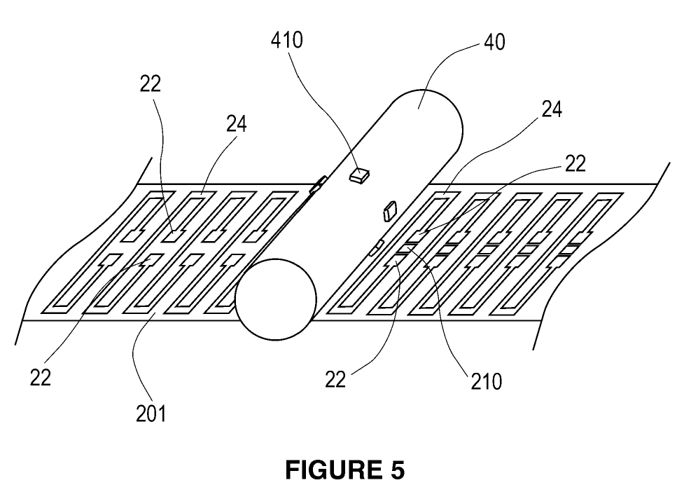

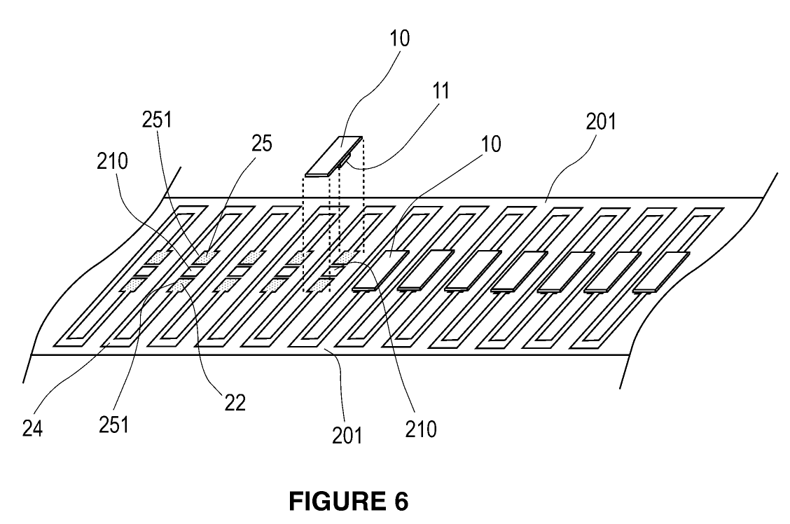

Next, a production method of the RFID medium 1 will be described. In the embodiment, as shown in FIG. 1, a chip mounting step of mounting the IC chip 11 on the surface of the chip holding member 13 to obtain the interposer 10, a housing portion forming step (see FIG. 5) of providing the chip housing portion 210 for housing the IC chip 11 in the antenna sheet 20, a stacking step (see FIG. 6) of stacking the antenna sheet 20 and the interposer 10 so that the IC chip 11 is housed in the chip housing portion 210, and a bonding step of bonding the antenna sheet 20 and the interposer 10 that are stacked are implemented in producing the RFID medium 1.

In the chip mounting step, as shown in FIGS. 2 and 3, a producing device (not shown, for example, a chip mounter) for mounting the IC chip 11 is used to mount the IC chip 11 on a predetermined position on the surface of the chip holding member 13. In this step, the chip holding member 13 having a conductive pattern including the interposer terminal 12 previously formed is used. Then, the IC chip 11 is bonded to the chip holding member 13 so as to achieve electrical connection with the interposer terminal 12.

Prior to implementing the housing portion forming step, a pattern printing step of forming the antenna pattern 24 (see FIG. 4) on the surface of the base member 21 is implemented. In the pattern printing step of the embodiment, the conductive ink is printed to form the antenna pattern 24 having a predetermined shape. Specifically, in the embodiment, a plurality of antenna patterns 24 are continuously formed on a surface of a continuous sheet 201 from which the antenna sheets 20 are stamped. As described above, each of the antenna patterns 24 has a substantially annular shape with a break at one position, and has the pair of base terminals 22 at the break.

Then, in the housing portion forming step, as shown in FIG. 5, the chip housing portion 210 passing through the antenna sheet 20 is formed in a gap between the pair of base terminals 22 on the antenna sheet 20. In the embodiment, the housing portion forming step is implemented using a rolling machine including a substantially cylindrical stamping roller 40 having a stamping blade 410 on an outer peripheral surface thereof. In this step, the chip housing portion 210 is provided in each antenna pattern 24 on the continuous sheet 20 by the stamping blade 410 of the stamping roller 40.

Next, as shown in FIG. 6, the stacking step of stacking the antenna sheet 20 and the interposer 10 is implemented. In the embodiment, the stacking step is implemented using the continuous sheet 201 before stamping of the antenna sheets 20. In the stacking step, first, an adhesive providing area 251 to which a conductive adhesive 25 is applied is provided on a surface of each of the pair of base terminals 22 on the continuous sheet 201. In the embodiment, the adhesive providing area 251 is provided so as to substantially match a forming area of the base terminal 22. Then, the interposer 10 and the antenna sheet 20 are caused to face each other to reduce a gap therebetween, and stacked so that the IC chip 11 is housed in the chip housing portion 210. Then, in the bonding step, the interposer 10 is pressed on the continuous sheet 201. In the embodiment, a press device including a pair of press dies (not shown) is used to press the interposer 10 and the continuous sheet 201 placed in a gap of the integral press dies.

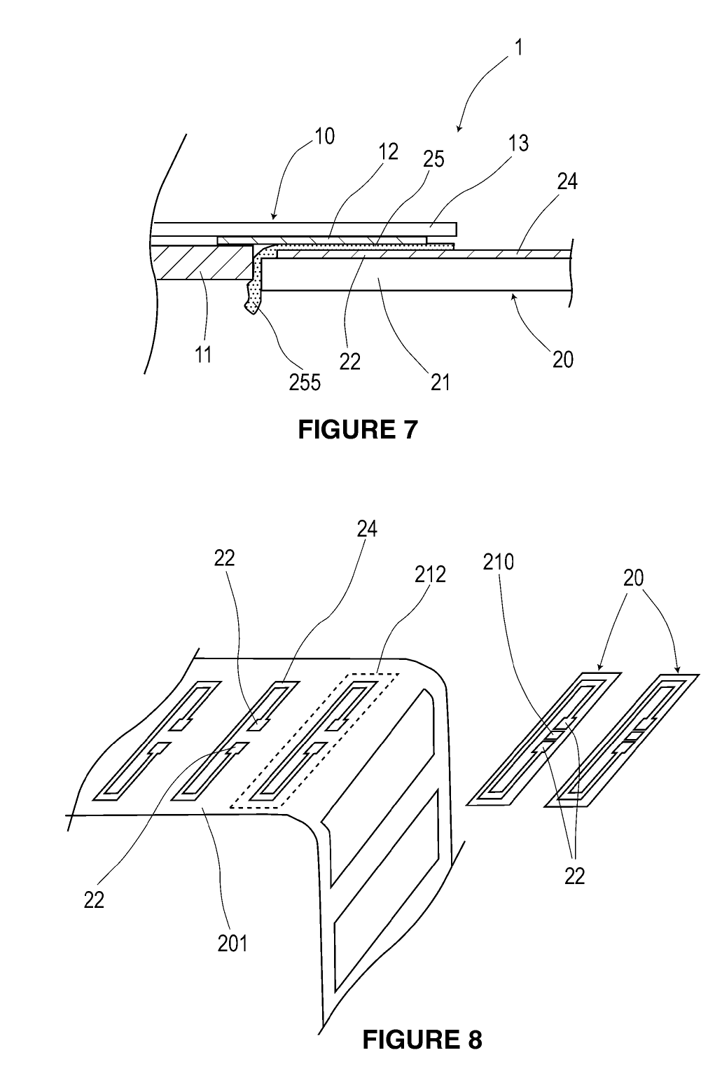

At this time, a connection between the conductive adhesives 25 on the adhesive providing areas 251 spaced apart with the chip housing portion 210 therebetween causes a problem such as an electrical short circuit. In the embodiment, the chip housing portion 210 between the pair of adhesive providing areas 251 effectively works against the problem. The through-hole-shaped chip housing portion 210 in the embodiment can effectively drain an excess conductive adhesive 25 to the outside (a portion denoted by reference numeral 255) as shown in FIG. 7. Thus, in the RFID medium 1, there is a low risk of causing trouble such as an electrical short circuit via the conductive adhesive 25.

When the chip housing portion 210 has a closed-end recessed shape instead of this embodiment, it is only necessary to control an application amount of the conductive adhesive 25 in the bonding step. Specifically, the application amount of the conductive adhesive 25 is controlled to a proper amount to prevent the risk of the connection between the conductive adhesives 25 on the pair of adhesive providing areas 251 in the bonding step.

### Embodiment 2

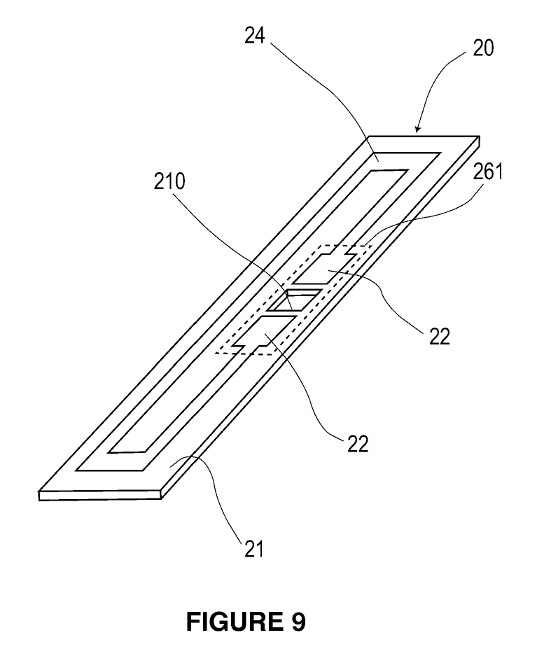

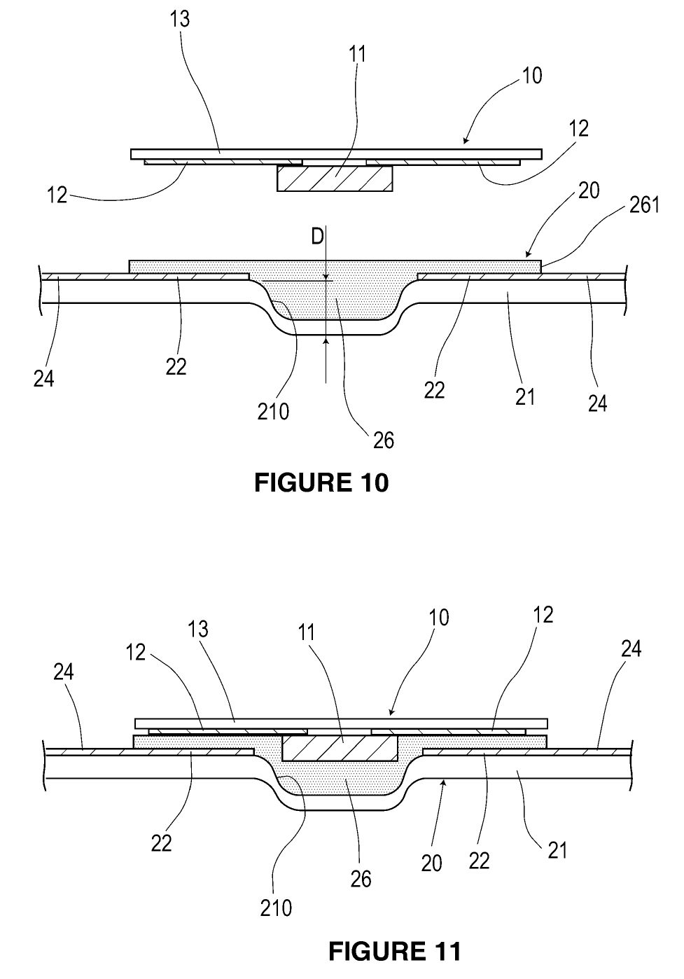

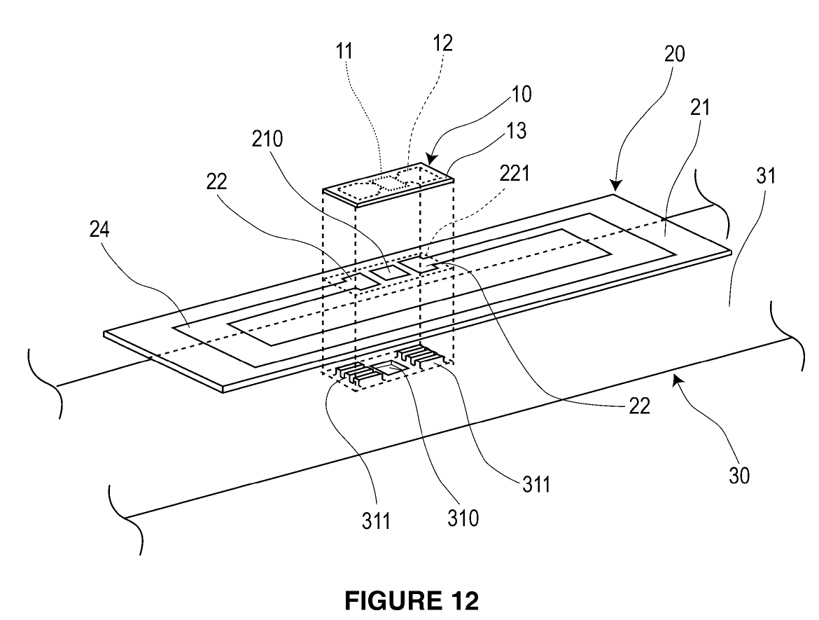

This embodiment is such that the chip housing portion 210 is changed to a recessed chip housing portion 210 based on the RFID medium in Embodiment 1, and an insulating adhesive 26 having electrical insulating properties is used as an adhesive. In a stacking step of the embodiment, the insulating adhesive 26 (FIG. 10) is used instead of the conductive adhesive in Embodiment 1. An adhesive providing area 261 is provided so as to substantially match a stacking area of an interposer 10 on a surface of an antenna sheet 20 (FIG. 9). The closed-end recessed chip housing portion 210 is formed. Further, in a bonding step of the embodiment, a press die 31 (FIG. 12) having protrusions 311 on a pressing surface is used to protrudingly deform the antenna sheet 20, thereby ensuring an electrical connection state between the interposer 10 and the antenna sheet 20 (FIGS. 12 to 14). This will be described with reference to FIGS. 8 to 14.

In a housing portion forming step in the embodiment, as shown in FIG. 8, the antenna sheet 20 is stamped from a continuous sheet 201 made of PET and having a thickness of 100 μm, and is formed with the recessed chip housing portion 210 by embossing. Specifically, the machining is implemented using a Thomson die cutter (not shown) having a Thomson blade having substantially the same shape as an outer peripheral shape of the antenna sheet 20 and having a protruding machining portion for embossing on an inner periphery of the Thomson blade. In the embodiment, for an IC chip 11 having a mounting height of 100 to 110 μm, a depth D (see FIG. 10) of the chip housing portion 210 is 130 μm, and for a size of 400 μm×400 μm of the IC chip 11, a size of the chip housing portion 210 is 800 μm×800 μm. FIGS. 10 to 13 show the IC chip 11 deformed in size, and show a gap between an outer edge of the chip housing portion 210 and the IC chip 11 in a relatively smaller scale than an actual scale.

It is also effective to select thermoplastic material as material for the continuous sheet 201, and provide a heater in the Thomson die cutter. In this case, the heated Thomson die cutter can be used to emboss the continuous sheet 201 made of thermoplastic material with high shape accuracy.

Next, in the stacking step, as shown in FIGS. 9 and 10, the adhesive providing area 261 having substantially the same shape as the outer shape of the interposer 10 is provided on the surface of the stamped antenna sheet 20. Then, as shown in FIG. 11, the interposer 10 and the antenna sheet 20 are stacked so that the IC chip 11 is housed in the chip housing portion 210 as in Embodiment 1.

In this embodiment, as the insulating adhesive 26, thermoplastic moisture-curable hot melt (Model No. TE-031 produced by 3-M corporation) is used. As the insulating adhesive 26, besides the above described one, an epoxy adhesive, an acrylic adhesive, an elastic adhesive, a urethane adhesive, or the like can be used. Further, instead of the moisture-curable insulating adhesive, a reactive insulating adhesive such as a heat-curable insulating adhesive, an ultraviolet-curable insulating adhesive, or an electron-beam-curable insulating adhesive may be used.

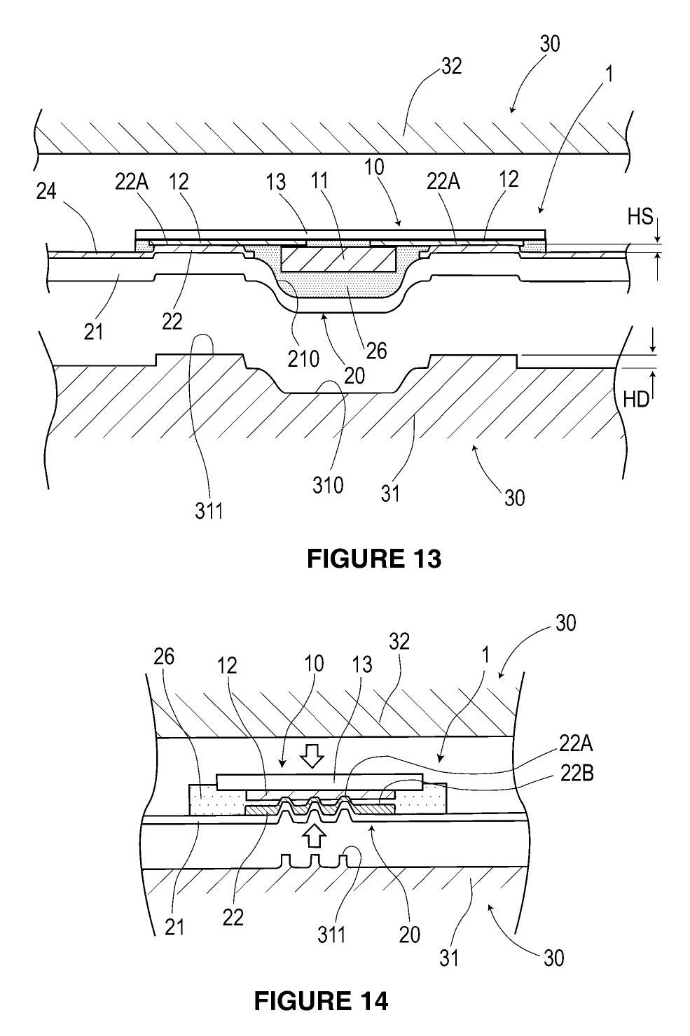

Next, in the bonding step, as shown in FIG. 12, the antenna sheet 20 and the interposer 10 placed in a gap between a pair of press dies 30 facing each other are pressed in the stacking direction thereof. On the other hand, as shown in FIGS. 12 to 14, the die 31 that abuts against the antenna sheet 20 has rib-like three protrusions 311 correspondingly to a forming position of each base terminal 22. In the embodiment, a protruding height HD of the protrusion 311 is set to 300 μm so that a protrudingly deformed portion 22A having a protruding height HS of about 50 μm can be formed on the base terminal 22 (see FIG. 13). In FIG. 12, the interposer 10 and the antenna sheet 20 are shown separated for convenience. The die 31 has a recessed guide portion 310 corresponding to a protrusion by the chip housing portion 210. A press die 32 (hereinafter referred to as a press anvil 32) on the side of the interposer 10 has a substantially flat pressing surface.

The protrusions 311 on the pressing surface of the die 31 may have various shapes such as a dotted shape, a cross shape, or a comb shape instead of the rib shape in the embodiment. In the embodiment, the protrusion 311 is provided on the die 31, but a protrusion may be provided on the pressing surface of the press anvil 32 instead. Further, protrusions may be provided on both the die 31 and the press anvil 32.

The die 31 in the embodiment includes an unshown heater for heating the pressing surface thereof. The heater can easily protrudingly deform the base member 21 made of thermoplastic material. Further, heating the insulating adhesive 26 can increase fluidity thereof.

In the bonding step in the embodiment, as shown in FIGS. 13 and 14, the die 31 having the pressing surface heated to 200° C. is used, and a state where a pressing force of about 13.5 MPa is applied between the die 31 and the press anvil 32 is maintained for about 0.1 second to press the antenna sheet 20 and the interposer 10.

In the bonding step, the action of the protrusions 311 of the die 31 can protrudingly deform part of each base terminal 22 on the antenna sheet 20. Specifically, a rib-like protrudingly deformed portion 22A corresponding to the rib-like protrusions 311 provided on the pressing surface of the die 31 can be formed in each base terminal 22 (FIG. 14). The antenna sheet 20 and the interposer 10 are brought into direct contact with each other via the rib-like protrudingly deformed portion 22A, while a gap is formed between the antenna sheet 20 and the interposer 10 in a non-protrudingly-deformed portion 22B other than the protrudingly deformed portion 22A.

Thus, the insulating adhesive 26 is drained from between the protrudingly deformed portion 22A and the interposer terminal 12, and the protrudingly deformed portion 22A is thermocompression bonded to the interposer terminal 12. This allows electrical connection between the interposer terminal 12 and the base terminal 22 with high reliability. On the other hand, the insulating adhesive 26 is not completely drained from between the non-protrudingly-deformed portion 22B and the interposer terminal 12, and an appropriate amount of insulating adhesive 26 remains. Thus, the interposer terminal 12 and the base terminal 22 can be bonded, that is, physically connected with high reliability via the insulating adhesive 26 remaining in the gap.

Further, in the embodiment, the adhesive providing area 261 in the stacking step substantially matches the area where the interposer 10 is provided. Thus, the interposer 10 faces the antenna sheet 20 via the insulating adhesive 26 over the entire surface facing the antenna sheet 20. Thus, the interposer 10 is firmly bonded to the antenna sheet 20 over the entire surface. Further, when the interposer 10 and the antenna sheet 20 are abutted against each other and pressed, the remaining insulating adhesive 26 spreads out to the outer peripheral surface of the interposer 10 and adheres thereto. Thus, besides the surface of the interposer 10, the outer peripheral surface of the interposer 10 acts as a bonding surface, and the interposer 10 is firmly bonded to the antenna sheet 20.

The insulating adhesive 26 used in the embodiment is a reactive moisture-curable adhesive. Thus, after the bonding step is implemented, the interposer 10 can be more completely bonded during storage of the produced RFID medium 1 or the like. In the bonding step, it is effective to use a press device including an ultrasonic vibrating unit. Using such a press device allows the interposer terminal 12 and the base terminal 22 to be fused by ultrasonic bonding in a position where both are brought into direct contact with each other to further increase reliability in electrical connection. Bonding the interposer terminal 12 and the base terminal 22 with a combination of thermocompression bonding and fusion by ultrasonic bonding allows a good electrical connection state to be maintained with high stability over a long use period of the RFID medium 1.

Further, in the embodiment, the insulating adhesive 26 is applied to cover the chip housing portion 210. Thus, the chip housing portion 210 can firmly hold the IC chip 11 via the insulating adhesive 26. Specifically, in the RFID medium 1 in the embodiment, a firm bonding structure can be achieved in which the protruding IC chip 11 wedges into the recessed chip housing portion 210. Thus, the RFID medium 1 in the embodiment has high bonding reliability and high quality with high durability. Other configurations and operation and effect are the same as in Embodiment 1.

### Embodiment 3

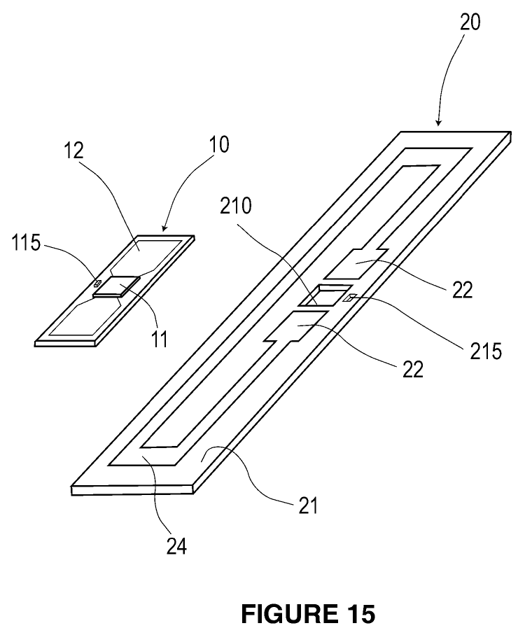

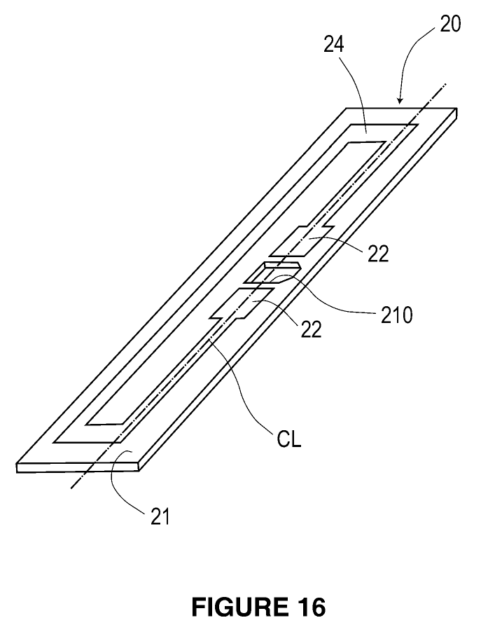

This embodiment is such that positioning reliability of the interposer 10 and the antenna sheet 20 is increased based on the RFID medium in Embodiment 1. This will be described with reference to FIGS. 15 and 16. As shown in FIG. 15, an interposer 10 in the embodiment has a protruding engaging portion 115 adjacent to an IC chip 11. An antenna sheet 20 in the embodiment has a through-hole-shaped engaged portion 215 adjacent to a chip housing portion 210. When the interposer 10 and the antenna sheet 20 are stacked, the engaging portion 115 and the engaged portion 215 fit each other. FIG. 15 shows the IC chip 11 deformed in size, and shows a gap between an outer edge of the chip housing portion 210 and the IC chip 11 in a relatively smaller scale than an actual scale.

The interposer 10 in the embodiment is configured so that the engaging portion 115 and the engaged portion 215 fit each other only when the interposer 10 is mounted to the antenna sheet 20 in a proper direction. Thus, with the combination of the interposer 10 having the engaging portion 115 and the antenna sheet 20 having the engaged portion 215, there is no risk of bonding with a wrong polarity of the interposer 10.

The engaged portion 215 may have a closed-end recessed shape or a through hole shape. In the embodiment, the interposer 10 has a protrusion, but the antenna sheet 20 may have a protruding engaged portion and the interposer 10 may have a recessed engaging portion instead. Further, as shown in FIG. 16, the engaged portion may be provided integrally with the chip housing portion 210. Specifically, a chip housing portion 210 asymmetrical with respect to a centerline CL connecting a pair of base terminals 22 is formed, and an asymmetrical protruding area is formed by the IC chip 11 and the engaging portion 115 (see FIG. 15) correspondingly to the asymmetrical shape of the chip housing portion 210, thereby obtaining the operation and effect of the embodiment. Other configurations and operation and effect are the same as in Embodiment 1.

1. An electronic component in which an interposer having a semiconductor chip mounted on a sheet-like chip holding member is bonded to a sheet-like base circuit sheet, characterized in that the interposer has the semiconductor chip mounted on a substantially planar surface of the chip holding member and has an interposer terminal that is a conductive pattern electrically extended from a terminal of the semiconductor chip, and the base circuit sheet has a base terminal electrically connected to the interposer terminal and includes a chip housing portion for housing the semiconductor chip.

2. The electronic component according to claim 1, characterized in that the chip holding member and the base circuit sheet are made of resin films.

3. The electronic component according to claim 2, characterized in that the chip housing portion has a shape of a recessed depression, and the recessed chip housing portion houses the semiconductor chip via an insulating adhesive having electrical insulating properties.

4. The electronic component according to claim 2, characterized in that the base circuit sheet has a through-hole-shaped chip housing portion, and has a pair of base terminals so as to face each other with the chip housing portion therebetween, and each of the base terminals is bonded to the interposer terminal via a conductive adhesive.

5. The electronic component according to claim 3, characterized in that the chip holding member has a protruding or recessed engaging portion with the base circuit sheet, and the base circuit sheet has an engaged portion configured to fit the engaging portion.

6. The electronic component according to claim 4, characterized in that the chip holding member has a protruding or recessed engaging portion with the base circuit sheet, and the base circuit sheet has an engaged portion configured to fit the engaging portion.

7. The electronic component according to any one of claims 1 to 6, characterized in that the base circuit sheet has an antenna pattern for radio communication constituted by a conductive pattern, and the semiconductor chip is an RFID IC chip.

8. A production method for producing an electronic component in which an interposer having a semiconductor chip mounted on a surface of a sheet-like chip holding member and having an interposer terminal that is a conductive pattern electrically extended from a terminal of the semiconductor chip is bonded to a sheet-like base circuit sheet having a base terminal electrically connected to the interposer terminal, characterized by including:
a chip mounting step of mounting the semiconductor chip on the surface of the chip holding member;
a housing portion forming step of providing a chip housing portion for housing the semiconductor chip in the base circuit sheet;
a stacking step of stacking the base circuit sheet and the interposer so that the semiconductor chip is housed in the chip housing portion; and a bonding step of bonding the base circuit sheet and the interposer that are stacked.

9. The production method for producing an electronic component according to claim 8, characterized in that the stacking step is a step of stacking the interposer on the base circuit sheet after applying an insulating adhesive having electrical insulating properties to at least a surface of the base terminal on the base circuit sheet, the bonding step is a step of pressing the base circuit sheet and the interposer using a pair of press dies facing each other, at least one of the base circuit sheet and the chip holding member is made of plastic material, and one of the press dies adjacent to the base circuit sheet or the chip holding member made of the plastic material has a protrusion protruding toward the other press die on a pressing surface facing a back surface of the interposer terminal or the base terminal.

10. The production method for producing an electronic component according to claim 9, characterized in that the insulating adhesive is thermoplastic, and the press die having the protrusion includes a heater for heating the pressing surface.

11. The production method for producing an electronic component according to claim 9, characterized in that the insulating adhesive is moisture-curable.

12. The production method for producing an electronic component according to claim 9, characterized in that ultrasonic vibration is applied between the interposer terminal and the base terminal in the bonding step.

13. The production method for producing an electronic component according to any one of claims 8 to 12, characterized in that the base circuit sheet has an antenna pattern constituted by a conductive pattern, and the semiconductor chip is an RFID IC chip.
